(19) United States
(12) Patent Application Publication
(10) Pub. No.: US 2025/0226360 A1
(43) Pub. Date: Jul. 10, 2025

(54) SEMICONDUCTOR PACKAGE

(71) Applicant: Samsung Electronics Co., Ltd., Suwon-si (KR)

(72) Inventors: Kyungdon Mun, Suwon-si (KR); Kimin Cheong, Suwon-si (KR)

(21) Appl. No.: 18/773,726

(22) Filed: Jul. 16, 2024

(30) Foreign Application Priority Data
Jan. 4, 2024 (KR) 10-2024-0001457

(51) Int. Cl. H01L 25/065; H01L 23/00; H01L 23/31; H01L 23/36; H01L 23/48; H01L 23/498; H01L 23/538; H10B 80/00

(52) U.S. Cl. CPC H01L 25/0652; H01L 23/5383; H01L 24/06; H01L 24/08; H01L 24/13; H01L 24/16; H01L 23/3107; H01L 23/36; H01L 23/481; H01L 23/49816; H01L 24/32; H01L 24/33; H01L 24/73; H01L 2224/0603; H01L 2224/08145; H01L 2224/13005; H01L 2224/16227; H01L 2224/32145; H01L 2224/32225; H01L 2224/33181; H01L 2224/73204; H10B 80/00

(57) ABSTRACT

A semiconductor package includes a first semiconductor chip including a semiconductor substrate and upper bonding pads disposed on an upper surface of the semiconductor substrate, and a bridge die disposed on the first semiconductor chip, and including a bridge substrate and first lower pads. The bridge substrate includes a first bridge portion and a second bridge portion. The first lower pads are disposed on a first lower surface of the first bridge portion of the bridge substrate and contact the upper bonding pads of the first semiconductor chip, respectively. When viewed in a plan view, the first bridge portion overlaps an edge portion of the first semiconductor chip and the second bridge portion extends beyond a side of the first semiconductor chip in a direction away from the edge portion of the first semiconductor chip. The bridge die and the first semiconductor chip are different types of semiconductor devices.

### CROSS-REFERENCE TO RELATED APPLICATION(S)

This application claims benefit of priority to Korean Patent Application No. 10-2024-0001457, filed on Jan. 4, 2024, in the Korean Intellectual Property Office, the disclosure of which is herein incorporated by reference in its entirety.

### BACKGROUND

The present inventive concept relates to a semiconductor package.

Electronic devices are becoming smaller and more lightweight according to the development of the electronics industry and user demand, and a semiconductor package used in electronic devices are desirable to have high performance and high capacity, along with miniaturization and weight reduction thereof. In order to implement high performance and high capacity, together with the miniaturization and weight reduction thereof, research and development of semiconductor chips including a through-silicon via (TSV) and semiconductor packages in which the semiconductor chips are stacked are continuously being conducted. Since interconnection between a plurality of semiconductor chips may not be guaranteed by a printed circuit board, the plurality of semiconductor chips may be connected by a separate interposer.

### SUMMARY

An aspect of the present inventive concept is to provide a semiconductor package including stacked semiconductor chips having improved structural reliability.

According to an aspect of the present disclosure, a semiconductor package includes a first semiconductor chip including a semiconductor substrate and a plurality of upper bonding pads disposed on an upper surface of the semiconductor substrate, and a bridge die disposed on the first semiconductor chip, and including a bridge substrate and a plurality of first lower pads. The bridge substrate includes a first bridge portion and a second bridge portion. The plurality of first lower pads are disposed on a first lower surface of the first bridge portion of the bridge substrate and contact the plurality of upper bonding pads of the first semiconductor chip, respectively. When viewed in a plan view, the first bridge portion overlaps an edge portion of the first semiconductor chip and the second bridge portion extends beyond a side of the first semiconductor chip in a direction away from the edge portion of the first semiconductor chip. The bridge die and the first semiconductor chip are different types of semiconductor devices.

According to a semiconductor package includes a redistribution structure including an insulating layer and an interconnection layer disposed within the insulating layer, and including a plurality of first upper contact pads and a plurality of second upper contact pads disposed on an upper surface of the insulating layer, a first semiconductor chip disposed on the redistribution structure and having a semiconductor substrate and a plurality of upper bonding pads disposed on an upper surface of the semiconductor substrate, at least one second semiconductor chip disposed around the first semiconductor chip on the redistribution structure, a bridge die disposed on the first semiconductor chip, and including a bridge substrate and a plurality of first lower pads and a plurality of second lower pads disposed on a lower surface of the bridge substrate, wherein the bridge substrate includes a first bridge portion and a second bridge portion, wherein the plurality of first lower pads are disposed on a first lower surface of the first bridge portion of the bridge substrate and contact the plurality of upper bonding pads, respectively, wherein the plurality of second lower pads are disposed on a second lower surface of the second bridge portion of the bridge substrate, wherein the first lower surface of the first bridge portion and the second lower surface of the second bridge portion is included in the lower surface of the bridge substrate, and wherein, when viewed in a plan view, the first bridge portion overlaps an edge portion of the first semiconductor chip and the second bridge portion extends beyond a side of the first semiconductor chip in a direction away from the edge portion of the first semiconductor chip, and a plurality of vertical conductive structures connecting the plurality of second lower pads of the bridge die to the plurality of second upper contact pads of the redistribution structure, respectively.

According to an aspect of the present disclosure, a semiconductor package includes a redistribution structure, a first semiconductor chip disposed on the redistribution structure, a plurality of second semiconductor chip disposed around the first semiconductor chip on the redistribution structure, a first-type bridge die partially overlapping the first semiconductor chip, a second-type bridge die partially overlapping the first semiconductor chip, wherein an area of the first-type bridge die is greater than an area of the second-type bridge die, and a plurality vertical conductive structures connecting each of the first-type bridge die and the second-type bridge to the redistribution structure. The first-type bridge die is electrically connected to M semiconductor chips among the plurality of second semiconductor chips. The second-type bridge die is electrically connected to N semiconductor chips among the plurality of second semiconductor chips. The first-type bridge die includes M memory controllers and a first cache memory. The second-type bridge die includes N memory controllers and a second cache memory. M is an integer equal to or greater than 2, N is an integer equal to or greater than 1, and M is greater than N. A memory capacity of the first cache memory is greater than a memory capacity of the second cache memory.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a diagram illustrating a semiconductor package according to example embodiments of the present inventive concept;

FIG. 2 is a schematic cross-sectional view illustrating an example embodiment taken along line I-I′ of FIG. 1;

FIG. 3 is a plan view illustrating the semiconductor package of FIG. 1 taken along line II-II′;

FIG. 4 is an enlarged cross-sectional view of region “A” of the semiconductor package of FIG. 1;

FIGS. 5 and 6 are enlarged cross-sectional views illustrating a semiconductor package according to another example embodiment of the present inventive concept;

FIGS. 7 to 9 are plan views illustrating semiconductor packages according to example embodiments of the present inventive concept;

FIG. 10 is a cross-sectional view illustrating the semiconductor package of FIG. 9 taken along line III-III′; and

FIGS. 11 to 13 are plan views illustrating semiconductor packages according to example embodiments of the present inventive concept.

### DETAILED DESCRIPTION

Hereinafter, example embodiments of the present inventive concept will be described in detail with reference to the attached drawings.

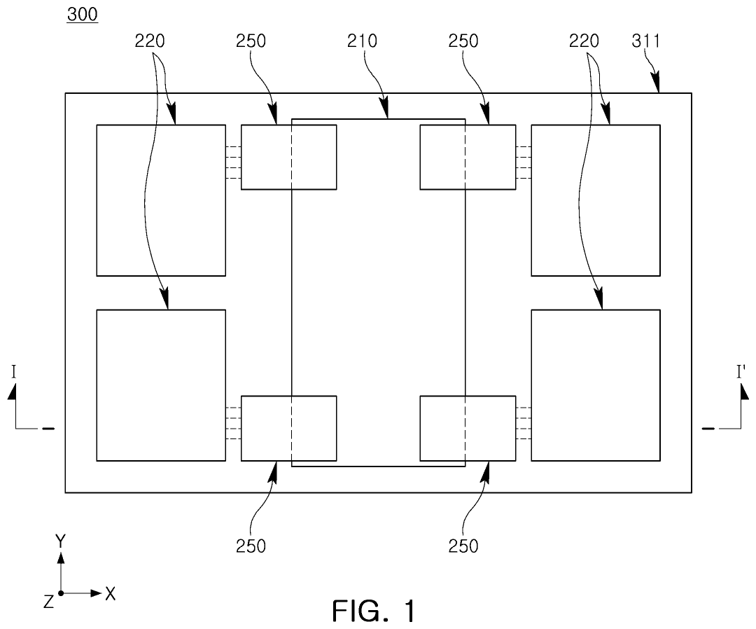

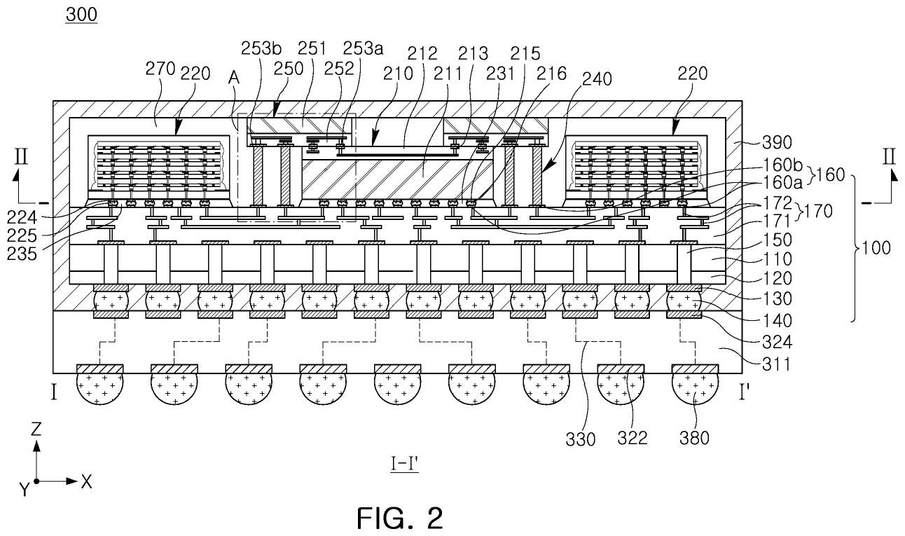

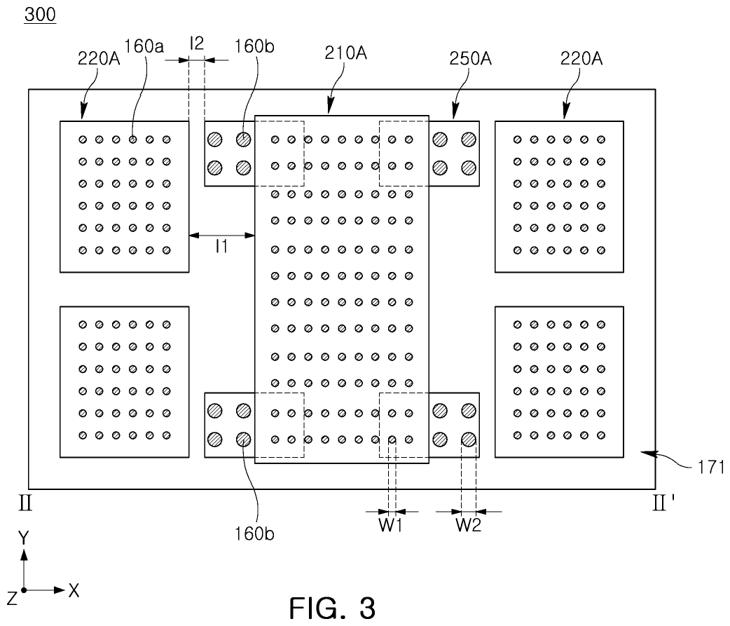

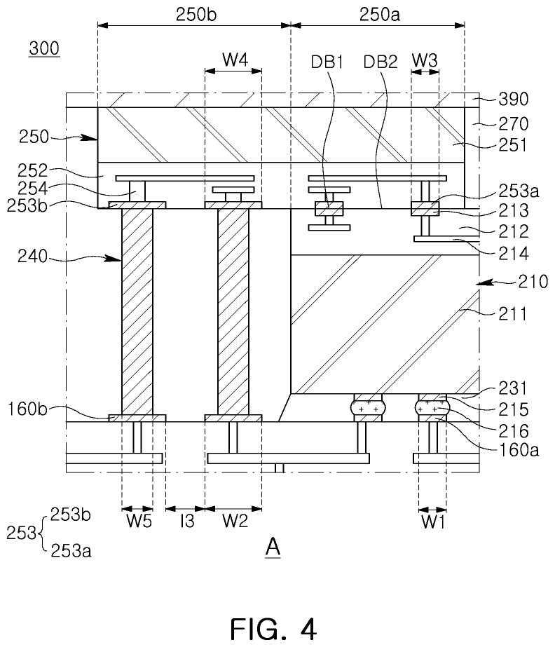

FIG. 1 is a diagram illustrating a semiconductor package according to example embodiments of the present inventive concept, FIG. 2 is a schematic cross-sectional view of an example embodiment taken along line I-I′ of FIG. 1, FIG. 3 is a plan view illustrating the semiconductor package of FIG. 1 taken along line II-II′, and FIG. 4 is an enlarged cross-sectional view of region “A” of the semiconductor package of FIG. 1.

Referring to FIGS. 1 to 4, the semiconductor package 300 may include a package substrate 311, an interposer 100, and a plurality of semiconductor chips 210, 220, and 250. In one example, the semiconductor package 300 may further include a logic chip or a processor chip 210 disposed adjacently to the memory semiconductor chips 220 on the interposer 100 and at least one bridge die 250 disposed on the processor chip 210.

In an example embodiment, the package substrate 311 may include a substrate body, an upper pad 324 disposed on an upper surface of the substrate body, a lower pad 322 disposed on a lower surface of the substrate body, and a redistribution circuit 330 electrically connecting the upper pad 324 and the lower pad 322 with each other. In an example, the package substrate 311 may be a support substrate on which the interposer 100, the processor chip 210, the bridge die 250, and the memory semiconductor chips 220 are mounted, and may be a substrate for a semiconductor package including a printed circuit board (PCB), a ceramic substrate, a glass substrate, or a tape wiring substrate.

In an example embodiment, the body of the package substrate 311 may include different materials depending on the type of substrate. For example, when the package substrate 311 is a printed circuit board, the package substrate 311 may have a form in which an interconnection layer is additionally stacked on one or opposite sides of a body copper clad laminate or a copper clad laminate. In an example, a solder resist layer may be formed on a lower surface and an upper surface of the package substrate 311. The upper and lower pads 324 and 322 and the redistribution circuit 330 may form an electrical path between the upper and lower surfaces of the package substrate 311. The upper and lower pads 324 and 322 and the redistribution circuit 330 may include or may be formed of a metal material. The upper and lower pads 324 and 322 and the redistribution circuit 330 may include or may be formed of at least one metal such as copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), and an alloy including two or metals thereof. In an example, the redistribution circuit 330 may include multilayer redistribution layers and vias connecting the same. An external connection terminal 380 connected to the lower pad 322 may be disposed on a lower surface of the package substrate 311. In an example, the external connection terminal 380 may include or may be formed of tin (Sn), indium (In), bismuth (Bi), antimony (Sb), copper (Cu), silver (Ag), zinc (Zn), lead (Pb), or an alloy thereof.

In an example embodiment, the interposer 100 may include a substrate 110, a lower protective layer 120, a lower pad 130, a bump 140, a through-electrode 150, and an interconnection structure 170 (i.e., a redistribution structure). In an example, a plurality of semiconductor chips 210, 220, and 250 may be stacked on the package substrate 311 via the interposer 100. In an example, the interposer 100 may electrically connect the plurality of semiconductor chips 210, 220, and 250 with each other. In an example, the substrate 110 may be formed of any one of silicon, organic, plastic, and glass substrates. When the substrate 110 is a silicon substrate, the interposer 100 may be referred to as a silicon interposer 100. When the substrate 110 is an organic substrate, the interposer 100 may be referred to as a panel interposer 100. In an example, the lower protective layer 120 may be disposed on a lower surface of the substrate 110, and the lower pad 130 may be disposed below the lower protective layer 120. The lower pad 130 may be connected to the through-electrode 150. The plurality of semiconductor chips 210, 220, and 250 and the package substrate 311 may be electrically connected to the bump 140 disposed below the lower pad 130.

In an example embodiment, the interconnection structure 170 may be disposed on an upper surface of the substrate 110, and may include an insulating layer 171 and a single-layer or multilayer interconnection layer 172. When the interconnection structure 170 has a multilayer wiring structure, wirings in different layers may be connected to each other through vertical contacts.

In an example embodiment, the through-electrode 150 may extend from the upper surface to the lower surface of the substrate 110 and penetrate the substrate 110. The through-electrode 150 may extend into the interior of the interconnection structure 170 and be electrically connected to the interconnections of the interconnection structure 170. The present disclosure is not limited thereto. The through-electrode 150 may extend up to the upper surface of the substrate 110 to contact a lower surface of the insulating layer 171. In an example, when the substrate 110 is silicon, the through-electrode 150 may be referred to as a Through Silicon Via (TSV). In an example, the interposer 100 may include only the interconnection layer 172 therein without the through-electrode 150.

In an example embodiment, the interposer 100 may serve to convert or transmit an input electrical signal between the package substrate 311 and the plurality of semiconductor chips 210, 220, and 250. That is, the interposer 100 may not include elements such as active elements such transistors or passive elements such as capacitors and resistors.

In an example embodiment, the interconnection structure 170 may be disposed above the through-electrode 150. For example, a dispositional relationship between the interconnection structure 170 and the through-electrode 150 may be relative.

In an example embodiment, the bump 140 may be disposed on a lower surface of the interposer 100, and may be electrically connected to the wiring of the interconnection structure 170. The interposer 100 may be stacked on the package substrate 311 through the bump 140. The bump 140 may be connected to the interconnection layer 172 of the interconnection structure 170 through the through-electrode 150 and the lower pad 130. In an example, the bump 140 may be repeatedly placed to form bumps 140, and the lower pad 130 may be repeatedly placed to form lower pads 130. Some pads of the lower pads 130 used for power or ground may be integrated and connected together to a correspond bump of the bumps 140, so that the number of the lower pads 130 may be greater than the number of the bumps 140.

In an example embodiment, the interposer 100 may further include upper pads 160 (i.e., upper contact pads) on the insulating layer 171 of the interconnection structure 170. For example, the interconnection structure 170 may include the upper pads 160.

Referring to FIGS. 3 and 1, the upper pads 160 may be disposed on the insulating layer 171 of the interconnection structure 170 of the interposer 100 and may include first upper pads 160a (i.e., first upper contact pads) disposed below the semiconductor chips 210 and 220 and second upper pads 160b (i.e., second upper contact pads) connected to the bridge die 250.

The upper pads 160 disposed on an upper surface of the interposer 100 may be allocated to each region of a processor chip region 210A, a memory structure region 220A, and a bridge die region 250A according to the plurality of semiconductor chips 210 and 220 disposed on the upper surface of the interposer 100. Specifically, the first upper pads 160a attached to the connection bumps 216 of the first semiconductor chip 210 may be disposed in the processor chip region 210A in which the first semiconductor chip 210, which is a processor, is disposed. The first upper pads 160a may also be disposed in the memory structure region 220A in which the second semiconductor chips 220, which are memory structures, are disposed. The first upper pads 160a disposed within each region of the processor chip region 210A and the memory structure region 220A may has substantially the same area with a circular or square planar shape. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

Meanwhile, a region in which the bridge die 250 is disposed and protrudes from above the first semiconductor chip 210, outside of the first semiconductor chip 210, may be defined as the bridge die region 250A, and the bridge die region 250A may be disposed in a continuous position without overlapping the processor chip region 210A.

The second upper pads 160b may be disposed within the bridge die region 250A. Vertical bumps 240 may be disposed on the second upper pads 160b to contact second lower pads 253b of the bridge die 250 in a Z-direction which is perpendicular to an upper surface of the package substrate 311. For example, the vertical bumps 240 may connect the second upper pads 160b to the second lower pads 253b of the bridge die 250, respectively. In an embodiment, vertical conductive structures electrically connecting the bridge die 250 to the interconnection structure 170 outside the first semiconductor chip 210 may include the vertical bumps 240 extending lengthwise in the Z-direction.

In an embodiment, each of the first upper pads 160a may have a first width W1 and a first area, and each of the second upper pads 160b may have a second width W2 and a second area. The second width W2 may be greater than the first width W1. The second area may be greater than the first area. In addition, the second upper pads 160b may have the same shape as the first upper pads 160a, for example, a circular shape, but may have a prismatic shape depending on the embodiment. When the second upper pads 160b have a circular or prismatic shape, the second area of the second upper pads 160b may be greater than the first area of the first upper pads 160a.

The second upper pads 160b disposed in the bridge die region 250A may be spaced apart from each other at a separation distance equal to or greater than a minimum separation distance. The minimum separation distance may be a separation distance in a range of 10 to 100 μm. In an embodiment, the minimum separation distance of the second upper pads 160b may be greater than a separation distance between the first upper pads 160a.

The semiconductor package 300 according to this embodiment may include a bridge die 250, and first and second semiconductor chips 210 and 220 mounted on the interposer 100. In an embodiment, the bridge die 250 may be repeatedly placed to form four bridge dies. The number of the bridge dies may have a number different from four. The first semiconductor chip 210 may be disposed to partially overlap each of the bridge dies 250, and complex signal lines in a PHY region may be connected to each other by the bridge dies 250. When the semiconductor package 300 (see FIGS. 1 and 3) is taken in plan view, a portion of the functional blocks in the first semiconductor chip 210 are shaped and disposed as separate chip structures (chipletz) as bridge dies 250, so that an area occupied by the first semiconductor chip 210 may be reduced in the semiconductor package 300, so that an area occupied by the memory semiconductor chips 220 may be secured. In addition, a portion of the functional blocks included in the first semiconductor chip 210, for example, a semiconductor structure such as a cache memory, and a functional block directly connected to the second semiconductor chip 220, such as a memory controller, may be mounted on the bridge die 250 as a separate chip structure. By forming the functional blocks of the first semiconductor chip 210 into separate chip structures and disposing the same to overlap the first semiconductor chip 210, the area of the first semiconductor chip 210 may be reduced and more memory chips may be mounted.

The second semiconductor chip 220 employed in this embodiment may include a high bandwidth memory chip. The second semiconductor chip 220 may include a plurality (e.g., four) of memory chips stacked and connected with each other. The plurality of memory chips may include a semiconductor substrate having an active surface and an inactive surface, opposing each other, respectively, a through-electrode penetrating the semiconductor substrate, and upper pads and lower pads. The upper pad of one memory chip may be connected to a lower pad of an adjacent memory chip. A lower pad of the memory chip disposed at the bottom may be connected to a redistribution pattern by a connection bump.

In a system where multiple individual semiconductor chips are packaged into one package, a number of memory dies included in the second semiconductor chip 220 may vary depending on the purpose of the semiconductor package 300. That is, the number of memory dies included in the second semiconductor chip 220 is not limited to the number as shown in the drawing. Each of the memory dies in the second semiconductor chip 220 may be adhered to another memory adjacent thereto through an adhesive member (not shown), and the memory dies may be stacked on each other. The adhesive member may be a non-conductive film.

In an example embodiment, an adhesive material layer may fill a space between the second semiconductor chip 220 and the interconnection structure 170 and a space between a plurality of memory dies in the second semiconductor chip 220, and may surround side surfaces of the plurality of memory dies in the second semiconductor chip 220. In one example, the adhesive material layer may include or may be formed of an epoxy material. For example, the adhesive material layer may be a non-conductive film (NCF), and an example embodiment thereof is not limited to such a material.

In an example embodiment, a mold layer 270 may be disposed to cover the second semiconductor chip 220 and the adhesive material layer and protect the second semiconductor chip 220 and the adhesive material layer from an external environment. In one example, the mold layer 270 may include or may be formed of an insulating material including a resin material such as an epoxy molding compound (EMC).

In some example embodiments, the second semiconductor chip 220 may include a volatile memory die and/or a non-volatile memory die. The volatile memory die may be, for example, dynamic random access memory (DRAM), static RAM (SRAM), thyristor RAM (TRAM), zero capacitor RAM (ZRAM), or twin transistor RAM (TTRAM). In addition, the non-volatile memory die may be, for example, flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, or insulator resistance change memory. The second semiconductor chip 220 may include a substrate at the bottom thereof, and may include lower bonding pads 224 below the substrate. The lower bonding pads 224 may be connected to the first upper pads 160a by connection bumps 225, and the lower bonding pads 224 and the connection bumps 225 may be protected by an underfill 235. For example, the underfill 235 may fill a space between the second semiconductor chip 220 and the interconnection structure 170 and surround each of the connection bumps 225. The mold layer 270 may cover and contact an exposed surface of the underfill 235 between the second semiconductor chip 220 and the interconnection structure 170.

In an example embodiment, the first semiconductor chip 210 is a processor chip, and may include, for example, a central processing unit (CPU), a graphics processing unit (GPU), a field programmable gate array (FPGA), a digital signal processor (DSP), a cryptographic processor, a microprocessor, a microcontroller, an analog-to-digital converter, a chipset, an audio codec, a video codec, an application processor, a system on chip, or an application-specific IC (ASIC). Depending on the types of elements included in the first semiconductor chip 210, the semiconductor package 300 may be classified into a server-oriented semiconductor package or a mobile-oriented semiconductor package.

The first semiconductor chip 210 may include a semiconductor substrate 211 having an active surface and an inactive surface, opposing each other, and lower bonding pads 215 on a lower surface of the semiconductor substrate 211. The lower bonding pads 215 may be connected to the first upper pads 160a by connection bumps 216. The lower bonding pads 215 may include a surface treatment layer formed to function as a pad. The surface treatment layer is not particularly limited as long as it is known in the art, and may be formed by, for example, electrolytic gold plating, electroless gold plating, Organic Solderability Preservative (OSP) or electroless tin plating, electroless silver plating, electroless nickel plating/substituted gold plating, Direct Immersion Gold (DIG) plating, or Hot Air Solder Levelling (HASL), but an example embodiment thereof is not limited thereto. In this embodiment, the first semiconductor chip 210 may further include a dielectric layer 212 (i.e., an upper insulating layer) disposed on an upper surface of the semiconductor substrate 211 and upper bonding pads 213 formed on the dielectric layer 212. The upper bonding pads 213 of the first semiconductor chip 210 may contact first lower pads 253a disposed on a lower surface of the bridge die 250. In an embodiment, the first lower pads 253a of the bridge die 250 may serve as bonding pads which contact the upper bonding pads 213 to form an inter-metal bonding DB1, which will be described later.

Underfills 231 and 235 surrounding the connection bumps 216 and 225 may be formed between each of the first and second semiconductor chips 210 and 220 and the interconnection structure 170. The underfills 231 and 235 may stably fix the first and second semiconductor chips 210 and 220 to the interposer 100. For example, the underfills 231 and 235 may be formed of a curable resin such as epoxy.

Referring to FIGS. 1 and 3, in the semiconductor package 300 according to this embodiment, a first semiconductor chip 210 may be disposed in a central region on the upper surface of the interposer 100, and second semiconductor chips 220 may be adjacent to the first semiconductor chip 210. The number of the second semiconductor chips 220 may be variously set, and in FIGS. 1 to 4, four second semiconductor chips 220 may be disposed such that two of the second semiconductor chips may be disposed to the left of the first semiconductor chip 210 and the other may be disposed to the right of the first semiconductor chip 210.

The two second semiconductor chips 220 disposed on one side of the first semiconductor chip 210 may be disposed side by side in a Y-direction and may be disposed to have a first separation distance I1 from the first semiconductor chip 210.

At least one bridge die 250 may be disposed on the first semiconductor chip 210. As described above, the bridge die 250 may be formed by forming some of the functional blocks of the first semiconductor chip 210 as a separate chip structure, and may include a memory controller and a cache memory in FIGS. 1 to 4.

The memory controller may be a functional block which is connected to each second semiconductor chip 220, and can write data to or read data stored in the second semiconductor chip by transmitting and receiving a signal. Accordingly, one memory controller may be disposed on each second semiconductor chip 220. A plurality of cache memories may be applied to the processor, and the cache memory is a buffer memory between the first semiconductor chip 210, which is a fast memory semiconductor chip, and the second semiconductor chip, which is a slow memory semiconductor chip. The cache memory may be defined as a general-purpose memory which compensates for the speed difference for storing the data in the second semiconductor chip 220 and using the data for operation of the first semiconductor chip 210. This type of cache memory is desirable to have a higher memory storage capacity as the function of the processor improves. The higher capacity the cache memory, the better the performance of the semiconductor package 300. The cache memory can be classified into L1, L2, and L3 cache memories, and the L1 cache memory may be a memory which is generally built in the first semiconductor chip 210 and used first for data use and reference. The L2 cache memory performs a similar function to the L1 cache memory, but when the L1 cache memory is first used, and desired data does not exist in the L1 cache memory, the processor can search the L2 cache memory. The L2 cache memory may be slower than L1 cache memory, but can be faster than general memory (RAM).

The L3 cache memory may perform a similar function to the L1 and L2 cache memories, and can function as a memory to find data which is not covered by the L2 cache memory. Therefore, when searching for data in the first semiconductor chip 210, it can be accessed in the order of L1-L2-L3 cache memory, and the higher the capacity of the L3 cache memory, the better the performance of the semiconductor package may be perceived. Therefore, expansion of the capacity of the L3 cache memory is continuously required, which may lead to an increase in the size of the first semiconductor chip 210. The increase in the size of the first semiconductor chip 210 on the semiconductor package 300 having a predetermined area, that is the interposer 100 may reduce the number of the second semiconductor chips 220, which may lead to an increase in vertical stacking of the second semiconductor chips 220, which may lead to an increase in process burden and an increase in the overall height of the package.

In an example embodiment of the present inventive concept, the memory controller and the L3 cache memory, which are most closely related to the second semiconductor chip 220, among some functional blocks of the first semiconductor chip 210, as separate chip structures, and such chip structures may be disposed on the first semiconductor chip 210 as a bridge die 250.

At least one bridge die 250 may be disposed on the first semiconductor chip 210, and as shown in FIGS. 1 to 4, the bridge dies 250 may be disposed to correspond one-to-one to each of the second semiconductor chips 220. Accordingly, when four second semiconductor chips 220 are disposed around one first semiconductor chip 210, four bridge dies 250 may be disposed on the first semiconductor chip 210.

Each of the bridge dies 250 may have the same area and the same shape, and may protrude from the first semiconductor chip 210 toward each of the corresponding second semiconductor chips 220. Specifically, on an X-Y plane, the bridge dies 250 may include a first region 250a (i.e., a first bridge portion) located on the first semiconductor chip 210, and a second region 250b protruding externally of the first semiconductor chip 210. An area of the first region 250a may be greater than that of the second region 250b, but an example embodiment thereof is not limited thereto.

When the plurality of bridge dies 250 are disposed on the first semiconductor chip 210, the plurality of bridge dies 250 may not be disposed in a central region of the first semiconductor chip 210, but may be limitedly disposed in each corner region or edge region of the first semiconductor chip 210. The central region of the first semiconductor chip 210 may generates a large amount of heat, so a device layer may not be disposed, and a heat dissipation chip or a heat dissipation layer may be disposed on the central region, but an example embodiment thereof is not limited thereto. The plurality of bridge dies 250 may be spaced apart from each other on the first semiconductor chip 210 and may be disposed so that the second region 250b overlaps a separation space between the first semiconductor chip 210 and the second semiconductor chip 220. In this case, the second region 250b may not overlap the second semiconductor chip 220 in the Z-direction, and may satisfy the separation distance I2 to be spaced apart from each other. For example, the bridge die 250 may be spaced apart from the second semiconductor device 220 adjacent thereto at the separation distance I2. Each bridge die 250 may be disposed so that the first region 250a contacts the upper surface of the first semiconductor chip 210. For example, each bridge die 250 may partially overlap the upper surface of the first semiconductor chip 210. Each bridge die 250 is described with reference to FIGS. 1 and 4.

The bridge die 250 may have a first region 250a attached to the first semiconductor chip 210, and a second region 250b protruding externally of the first semiconductor chip 210 to overlap the separation space. The bridge die 250 may serve to connect the first semiconductor chip 210 and the second semiconductor chip 220 with each other.

Referring to FIG. 4, the bridge die 250 employed in this embodiment includes a semiconductor block 251 (i.e., a bridge substrate), a dielectric layer 252 disposed on a lower surface of the semiconductor block 251, and interconnection layers 254 formed on the dielectric layer 252. In this specification, the bridge die 250 is referred to as a “semiconductor bridge.” The interconnection layers 254 may include lower pads 253 disposed on a lower surface of the bridge die 250. The semiconductor block 251 may be, for example, a silicon (Si) block. The interconnection layers 254 may include conductor patterns and vias connecting the same. The conductor pattern and via may be formed into a fine structure using a semiconductor process. The conductor pattern of the interconnection layers 254 may have a small width. For example, the width and distance of the conductor patterns may be 1 μm or less, respectively.

The lower pads 253 may include first lower pads 253a disposed in the first region 250Ba and second lower pads 253b disposed in the second region 250b.

The first lower pads 253a may contact the upper bonding pads 213 of the first semiconductor chip 210 to form a physical/electrical connection, and the second lower pads 253b may be connected to vertical bumps 240 to be connected to the second upper pads 160b of the interposer 100. For example, the first lower pads 253a of the bridge die 250 may serve as bonding pads which contact the upper bonding pads 213 of the first semiconductor chip 210, and the second lower pads 253b of the bridge die 250 may serve as contact pads which are connected to the vertical bumps 240.

The second lower pads 253b may overlap the second upper pads 160b of the interposer 100 in the Z-direction, and may be electrically/physically connected thereto by vertical bumps 240 which extend lengthwise along a straight line extending in the Z-direction.

In an embodiment, each of the first lower pads 253a of the bridge die 250 may have a third width W3 and a third area, and each of the second lower pads 253b of the bridge die 250 may have a fourth width W4 greater than the third width W3 and a fourth area greater than the third area. The shapes of the second lower pads 253b and the first lower pads 253a may be different from each other. For example, the first lower pads 253a may have a circular or square shape such as the first upper pads 160a of the interposer 100, and the second lower pads 253b may have a circular or square shape. In an embodiment, lower surfaces of the first lower pads 253a and the second lower pads 253b may be located at the same level.

The bridge die 250 and the first semiconductor chip 210 may be connected by hybrid bonding, which is a connection process between semiconductor chips. Specifically, the first lower pads 253a of the bridge die 250 may be directly bonded to the upper bonding pads 213 of the first semiconductor chip 210 to form an inter-metal bonding DB1. The inter-metal bonding DB1 may bond the bridge die 250 to the first semiconductor chip 210 and simultaneously ensure electrical connectivity between the bridge die 250 and the first semiconductor chip 210. The dielectric layer 252 may be formed on a lower surface of the semiconductor block 251. The dielectric layer 252 may have a substantially flat upper surface, flush with the first lower pads 253a. For example, the first lower pads 253a may be exposed at a lower surface of the dielectric layer 252. The dielectric layer 212 of the first semiconductor chip 210 and the lower bonding insulating layer of the bridge die 250 may be directly bonded to form an inter-dielectric bonding DB2. No adhesive layer may be present at the inter-metal bonding DB1 and the inter-dielectric bonding DB2.

The vertical bump 240 employed in this embodiment is a conductive post, and may be provided as a path to vertically connect the interposer 100 and the bridge die 250 with each other. The vertical bump 240 may be formed through a plurality of plating processes (e.g., once) to form a desired height of the vertical bump 240. The present disclosure is not limited thereto. In an embodiment, the vertical bump 240 may be an integrated post formed of a single layer. The vertical bump 240 may be implemented as an alloy including a conductive material such as copper, but an example embodiment thereof is not limited thereto. The vertical bump 240 may connect the second upper pads 160b of the interposer 100 and the second lower pads 253b of the bridge die 250. The second upper pads 160b of the interposer 100 may have greater areas than the first upper pads 160a of the interposer 100. The second lower pads 253b of the bridge 250 may have greater areas than the first lower pads 253a. In addition, the vertical bumps 240 may be disposed to be spaced apart from adjacent vertical bumps 240 to have a predetermined separation distance. The predetermined separation distance may be a separation distance in a range of 200 μm to 400 μm. In an embodiment, the separation distance may be in a range of 250 μm to 350 μm. In an embodiment, the vertical bump 240 may have a fifth width W5 which is smaller than an width (e.g., the second width W2) of each of the second upper pad 160b and the second lower pad 253b. The fifth width W5 may have a value in a range of 150 μm to 250 μm.

The molding layer 270 may seal the upper surfaces of the first and second semiconductor chips 210 and 220 and the bridge die 250, to serve to protect the first and second semiconductor chips 210 and 220 and the bridge die 250 from an external environment. In the molding layer 270, an appropriate amount of molding resin may be inserted into the upper surface of the interposer 100, and an exterior of the semiconductor package 300 may be formed through a curing process. In some example embodiments, the molding resin may include an epoxy-group molding resin or a polyimide-group molding resin. The molding layer 270 may serve to protect the first and second semiconductor chips 210 and 220 from external influences such as impacts, or the like. In some example embodiments, the molding layer 270 may be formed to surround the upper surfaces of the first and second semiconductor chips 210 and 220. In other example embodiments, the molding layer 270 may be formed to expose the upper surfaces of the first and second semiconductor chips 210 and 220 externally.

The semiconductor package 300 employed in this embodiment may further include a heat dissipation member 390. The heat dissipation member 390 may be, for example, a heat slug or a heat sink. The heat dissipation member 390 may be in contact with an upper surface of the package substrate 310, and may be provided to surround the semiconductor package 300. The heat dissipation member 390 may directly contact the upper surfaces of the first and second semiconductor chips 210 and 220, but an example embodiment thereof is not limited thereto. The term “contact,” or “in contact with” as used herein, refers to a direct connection (i.e., physical touching) unless the context indicates otherwise.

In some example embodiments, a thermally conductive interface material (TIM) layer may be disposed between the heat dissipation member 390 and the upper surfaces of the first and second semiconductor chips 210 and 220. In some example embodiments, the heat dissipation member 390 may be formed with an electromagnetic interference (EMI) shielding layer, and the electromagnetic interference (EMI) shielding layer may be electrically connected to a ground layer of the package substrate 311.

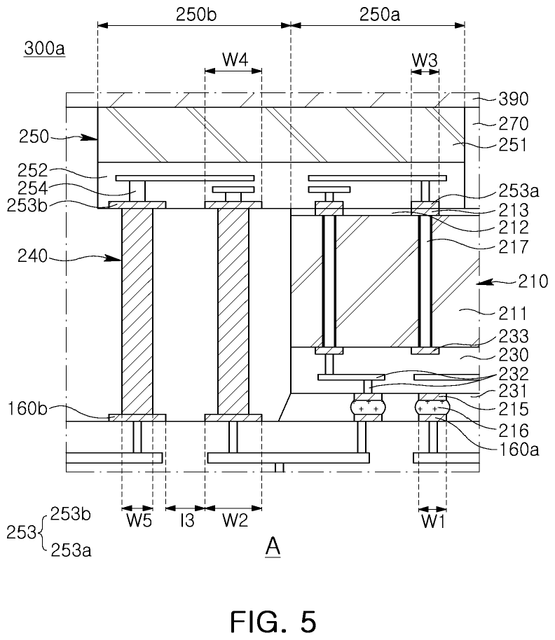

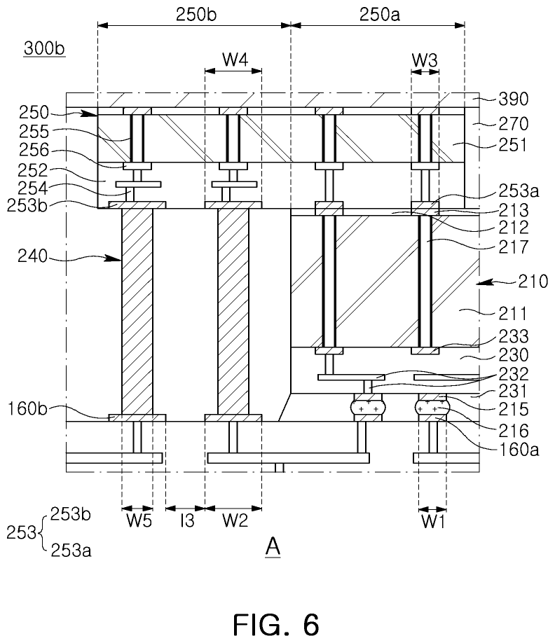

FIGS. 5 and 6 are enlarged cross-sectional views illustrating semiconductor package according to embodiments of the present inventive concept. FIGS. 5 and 6 are enlarged cross-sectional views of region ‘A’ in FIG. 1, as shown in FIG. 4.

Referring to FIG. 5, the semiconductor package 300a according to this embodiment is similar to the semiconductor package 300 as described with reference to FIGS. 1 to 4, except that the first semiconductor chip 210 of a different structure was adopted. Unless otherwise stated, the description of the components of this embodiment may refer to the description of the same or similar components of the semiconductor package 300 as shown in FIGS. 1 to 4.

The semiconductor package 300a of FIG. 5 may include a through-electrode 217 (i.e., a first through-electrode) penetrating the first semiconductor chip 210 and connecting the upper bonding pads 213 of the first semiconductor chip 210 and the interconnection layer 232 with each other. The through-electrodes 217 may extend from the upper surface to the lower surface of the semiconductor substrate 211 and penetrate the semiconductor substrate 211. The through-electrode 217 may extend to the interconnection structure 230 and may be electrically connected to the interconnection layer 232 through a wiring pad 233 of the interconnection structure 230. For example, the upper bonding pads 213 and the wiring pads 233 of the interconnection structure 230 may overlap in the Z-direction, and the through-electrodes 217 extending along a straight line extending in the Z-direction may connect the upper bonding pads 213 and the wiring pads. In an example, when the semiconductor substrate 211 is formed of silicon, the through-electrode 217 may be referred to as a Through Silicon Via (TSV).

Referring to FIG. 6, the semiconductor package 300b according to this embodiment is similar to the semiconductor package 300 as described with reference to FIGS. 1 to 4, except that the first semiconductor chip 210 and the bridge die 250 of different structures are employed. Unless otherwise stated, the description of the components of this embodiment may refer to the description of the same or similar components of the semiconductor package 300 as shown in FIGS. 1 to 4.

The semiconductor package 300b of FIG. 6 may include a through-electrode 217 penetrating the first semiconductor chip 210 and connecting the upper bonding pads 213 and the lower interconnection layer 232 with each other, and the bridge die 250 may include a through-electrode 255 (i.e., a second through-electrode) penetrating the semiconductor block 251. The through-electrode 217 of the first semiconductor chip 210 may be the same as that described in FIG. 5. The bridge die 250 may further include a redistribution structure below the semiconductor block 251. The redistribution structure of the bridge die 250 may include a dielectric layer 252 and interconnection layers 254. It can be understood that the interconnection layers 254 include first lower pads 253a and second lower pads 253b.

The through-electrodes 255 of the bridge die 250 may extend from the upper surface to the lower surface of the semiconductor block 251 to penetrate the semiconductor block 251. The through-electrode 255 may penetrate the semiconductor block 251 and may be electrically connected to the interconnection layers 254 through an interconnection upper pad 256 of the interconnection layers 254. The interconnection upper pad 256 may be disposed on an upper surface of the dielectric layer 252. In an example, when the semiconductor block 251 is formed of silicon, the through-electrode 255 may be referred to as a Through Silicon Via (TSV).

The bridge die 250 may further include an upper pad 258 connected to the through-via 255 and disposed on the upper surface of the semiconductor block 251 of the bridge die 250.

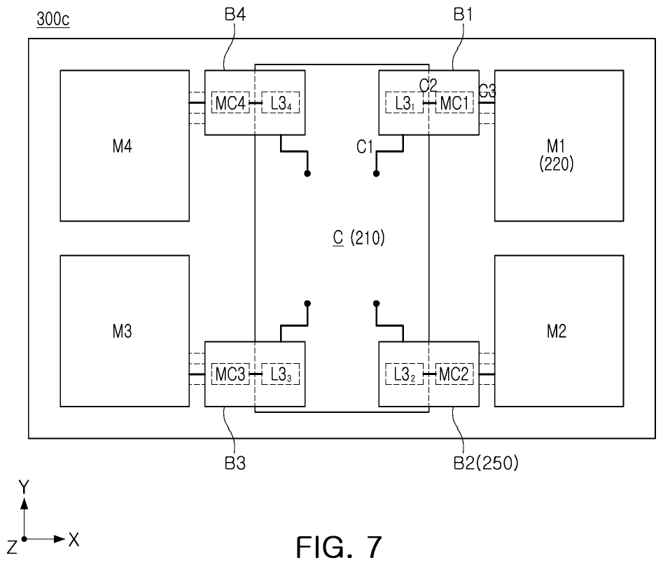

Hereinafter, with reference to FIGS. 7 to 13, various examples of disposition and relationships of electrical connection of semiconductor packages according to various example embodiments of the present inventive concept will be described.

FIG. 7 illustrates electrical connectivity in the semiconductor package 300 of FIGS. 1 to 6.

Referring to FIG. 7, as a processor, an electrical signal from the first semiconductor chip 210 (C) may be transmitted to bridge dies 250 (B1 to B4) by the upper bonding pads 213 of the first semiconductor chip 210 (C) and the first lower pads 253a of the bridge dies 250 (B1 to B4), which are in contact with each other by hybrid bonding C1. When each of the bridge dies 250 (B1 to B4) includes memory controllers MC1 to MC4 and L3 cache memories L3₁to L3₄in the bridge dies 250 (B1 to B4), the memory controller MC may operate according to the corresponding electrical signal, and the electrical signal may be transmitted to the second semiconductor chip 220 via an electrical connection including the connection between the second lower pad 253b and the vertical bump 240 and a pad connection C3 between the interconnection layer 172 of the interposer 100 and the second semiconductor chip 220. An electrical signal from the second semiconductor chip 220 may be also transmitted and stored in the cache memory L3 through the memory controller MC. For example, the electrical signal from the second semiconductor chip 220 may be transmitted via the pad connection C3 including the interconnection layer 172 of the interposer 100 and the vertical bump 240 to the bridge die 250, and the electrical signal therefrom may be transmitted to the first semiconductor chip 210 through hybrid bonding C1.

As described above, the functional blocks within the first semiconductor chip 210 may be formed into a separate chip structure, which may be disposed on the first semiconductor chip 210 as bridge dies 250 (B1 to B4). The functional blocks of the bridge dies 250 may be connected to the first semiconductor chip 210 through hybrid bonding. One side of the bridge dies 250 (B1 to B4) may be configured to protrude to overlap the interposer 100 to form an electrical path connected to the interposer 100 through a separate vertical bump 240.

Therefore, an area of the first semiconductor chip 210 may be significantly reduced through vertical stacking of the bridge dies 250 and the first semiconductor chip 210, and more space may be allocated for the second semiconductor chip 220, which is a memory block. An area of the semiconductor package 300 may be significantly reduced, and memory capacity such as cache memory, or the like, may be significantly increased.

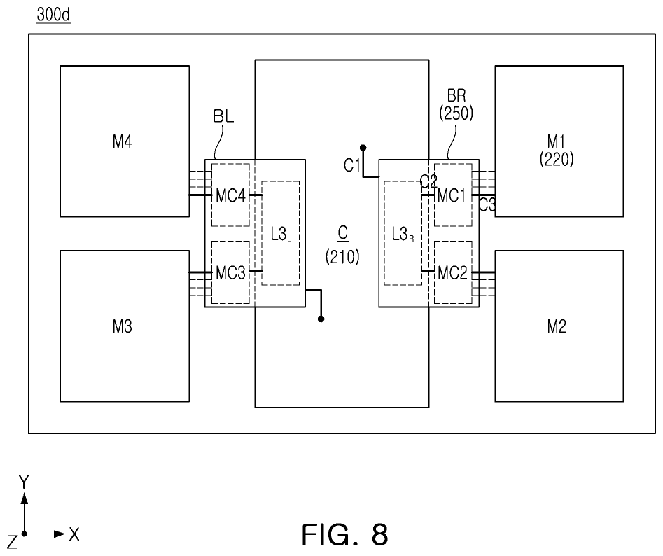

Referring to FIG. 8, in the semiconductor package 300d according to this embodiment, a first semiconductor chip 210 (C) may be disposed in a central region thereof on an upper surface of the interposer 100, and a plurality of semiconductor chips 220 (M1 to M4) may be disposed on opposite sides of the first semiconductor chip 210. The number of the second semiconductor chips 220 may be variously set, and in FIG. 8, it is the same as that in FIGS. 1 to 7 in that the four second semiconductor chips 220 are disposed. Two of the four second semiconductor chips 220 may be disposed on the left side of the first semiconductor chip 210, and the others may be disposed on the right side of the first semiconductor chip 210.

Two bridge dies 250 (B_{R} and B_{L}) may be disposed above the first semiconductor chip 210. The bridge die 250 may include a right bridge die 250 (B_{R}) disposed on the right side and a left bridge die 250 (B_{L}) disposed on the left side. The bridge dies 250 may have the same configuration and size, and may be symmetrically disposed on the first semiconductor chip 210. As described above, the bridge die 250 may be formed by forming some of the functional blocks of the first semiconductor chip 210 as a separate chip structure, and each of the bridge dies (B_{R} and B_{L}) may include memory controllers and cache memory.

The memory controllers MC1 to MC4 may be connected to the first semiconductor chip 210, and may be functional blocks that can write data to or read data stored in the second semiconductor chip 220 (M1 to M4) by transmitting and receiving signals. Accordingly, the memory controllers (MC1 to MC4) may correspond to the second semiconductor chips 220 (M1 to M4), respectively. The first and second memory controllers MC1 and MC2 may be disposed within the right bridge die 250 (B_{R}), and may be electrically connected to share a right L3 cache memory (L3_{R}). The third and fourth memory controllers MC3 and MC4 may be disposed within the left bridge die 250 (B_{L}), and may be electrically connected to share a left L3 cache memory (L3_{L}).

Accordingly, the electrical signal from the first semiconductor chip 210 may be transmitted to the bridge die 250 by the upper bonding pad 213 of the first semiconductor chip 210 and the first lower pad 253a of the left and right bridge die 250 (B_{R} and B_{L}) which contact each other to form hybrid bonding C1. The bridge die 250 may perform operations on specific memory controllers (MC1 to MC4) using the corresponding electrical signal, and the electrical signal may be transmitted to the second semiconductor chip 220 via an electrical connection including the connection between the second lower pad 253b and the vertical bump 240 and the pad connection C3 between the interconnection layer 172 of the interposer 100 and the second semiconductor chip 220. The electrical signal from the second semiconductor chip 220 may also be stored in the cache memories (L3_{R}, L3_{L}) through the interconnection layer 172 of the interposer 100, the vertical bump 240, the memory controllers MC1 to MC4 of the bridge die 250 of the pad connection C3, and may also be transmitted to the first semiconductor chip 210 through hybrid bonding C1. Accordingly, the L3 cache memories (L3_{R}, L3_{L}) for storing data of the plurality of second semiconductor chips 220 may be shared in each bridge die 250, and even when two bridge dies 250 are disposed, a separate die may not be disposed in the central region of the first semiconductor chip 210, and may be disposed to be exposed externally (i.e., may extend beyond a side of the first semiconductor chip 210 in a direction away therefrom).

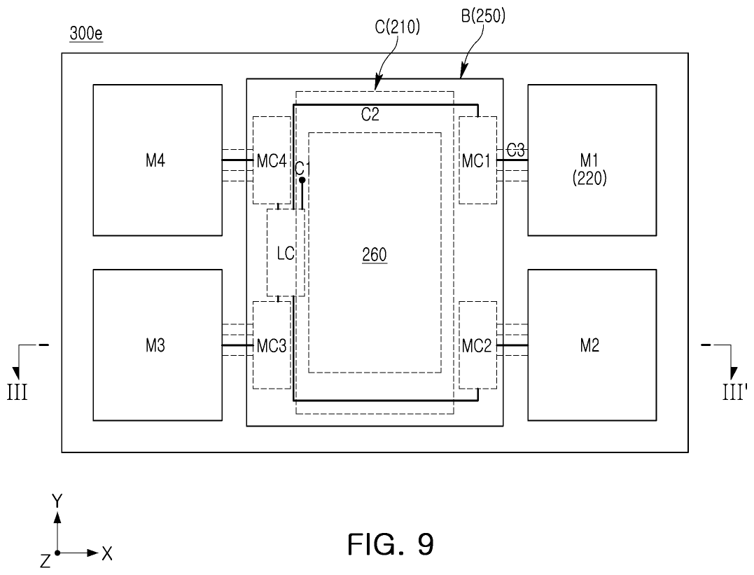

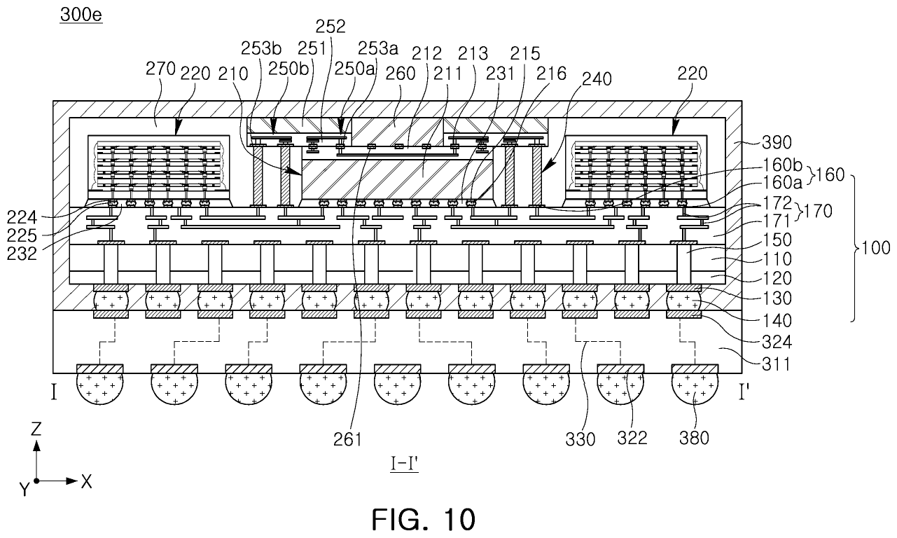

FIGS. 9 and 10 illustrate a semiconductor package according to an embodiment of the present inventive concept. FIG. 9 illustrates the disposition of a semiconductor package in an embodiment, and FIG. 10 is a cross-sectional view of the semiconductor package of FIG. 9 taken along line III-III′.

Referring to FIGS. 9 and 10, a semiconductor package 300e according to the present embodiment is the same as the semiconductor packages as shown in FIGS. 1 to 7, in that a first semiconductor chip 210 is disposed in a central region thereof on an upper surface of the interposer 100, and four second semiconductor chips 220 M1 to M4 are disposed while surrounding the first semiconductor chip 210 C.

One bridge die 250 B may be disposed on the first semiconductor chip 210. The bridge die 250 B may cover the entire upper surface of the first semiconductor chip 210, and may include a first region 250a overlapping the first semiconductor chip 210 and a second region 250b protruding outwardly of the first semiconductor chip 210 (i.e., extending beyond a side of the first semiconductor chip 210 in a direction away therefrom). As described above, in the bridge die 250, a portion of functional blocks of the first semiconductor chip 210 may be formed as a separate chip structure, and the bridge die 250 may include memory controllers MC1 to MC4 and a cache memory L3. The memory controllers MC1 to MC4 may be connected to the second semiconductor chips M1 to M4, respectively. In this case, the plurality of memory controllers MC1 to MC4 may be disposed with the bridge die 250, and may be electrically connected to share one L3 cache memory L3.

In this case, as shown in FIG. 10, a heat dissipation portion 260 may be disposed in the central region of the bridge die 250, that is, the central region of the first semiconductor chip 210. The heat dissipation portion 260 may not be formed as a device, but may be buried with a material with high thermal conductivity, such as bulk silicon. Accordingly, heat generated in the central region of the first semiconductor chip 210 may be conducted and discharged externally.

The bridge die 250 may include a dielectric layer 252 and lower pads 253 which are disposed below the heat dissipation portion 260. The lower pads 253 may include copper having high conductivity, or the like, and may be effective in heat conduction. When one bridge die 250 is disposed on a plurality of second semiconductor chips 220, a second region 250b protruding to be adjacent to each of the second semiconductor chips 220 may be disposed. Accordingly, the area of the bridge die 250 may be greater than that of the first semiconductor chip 210. In addition, a width of the second region 250b protruding into a separation space may be greater than a width of a region protruding to a side in which the second semiconductor chip 220 is not disposed. Even if the heat dissipation portion 260 is disposed in a central region of the bridge die 250, an upper surface of the bridge die 250 may be formed so that the heat dissipation portion 260 and the semiconductor block 251 are coplanar. A structure for signal connection between the first semiconductor chip 210, the bridge die 250, the interposer 100, and the second semiconductor chip 220 is the same as described above, and one cache memory can be shared.

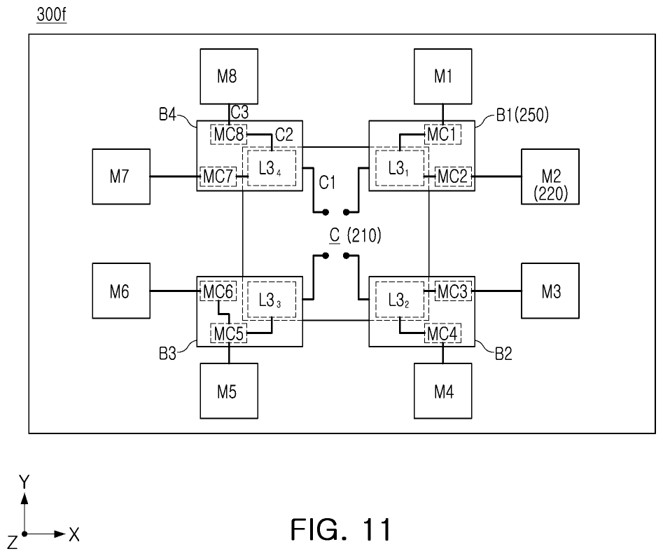

Referring to FIG. 11, in the semiconductor package 300f according to this embodiment, a first semiconductor chip 210 (C) may be disposed on an upper surface of the interposer 100, and second semiconductor chips 220 (M1 to M8) may surround the first semiconductor chip 210 (C). The second semiconductor chips 220 (M1 to M8) may be variously set, and in FIG. 8, eight second semiconductor chips 220 (M1 to M8) be disposed on four sides of the first semiconductor chip 210. For example, two second semiconductor chips may be adjacent to each side of the first semiconductor chip 210.

Four bridge dies 250 (B1 to B4) may be disposed above the first semiconductor chip 210. When the four bridge dies 250 (B1 to B4) have a square shape, one vertex thereof may be disposed on the first semiconductor chip 210, and the remaining three vertices thereof may be disposed to protrude from the first semiconductor chip 210. The four bridge dies 250 (B1 to B4) may be interconnected to the interposer 100 through a vertical bump 240 below the protruding second region 250b.

The configuration and size of each of the bridge dies 250 (B1 to B4) may be all the same, and may be symmetrically disposed on the first semiconductor chip 210. As described above, the bridge dies 250 (B1 to B4) is formed by forming a portion of the functional blocks of the first semiconductor chip 210 into a separate chip structure, and the bridge dies 250 (B1 to B4) may include memory controllers MC1 to MC8 and cache memories L3₁ to L3₄. Each bridge die 250 (B1-B4) includes two memory controllers MC1, MC2 in which one die is connected to two adjacent first and second semiconductor chips 220 (M1, M2), may be electrically connected to share L3 cache memory L3₁.

Accordingly, the electrical signal from the first semiconductor chip 210 may be transmitted to the bridge die 250 by hybrid bonding C1, and the bridge die 250 may perform operations on specific memory controllers (MC1 to MC8) using the corresponding electrical signal, and the electrical signal may be transmitted to the second semiconductor chip 220 via an electrical connection including the connection between the second lower pad 253b and the vertical bump 240 and the pad connection C3 between the interconnection layer 172 of the interposer 100 and the second semiconductor chip 220. The electrical signal from the second semiconductor chip 220 may also be stored in the cache memory (L3) in the memory controller MC through the interconnection layer 172 of the interposer 100, the vertical bump 240, and the bridge die 250 of the pad connection C3, and may also be transmitted to the first semiconductor chip 210 through hybrid bonding C1. Accordingly, the L3 cache memory (L3) for storing data of the plurality of second semiconductor chips 220 may be shared in each bridge die 250, and even when four bridge dies 250 (B1 to B4) are disposed, a separate die may not be disposed in the central region of the first semiconductor chip 210, and may be disposed to be exposed externally (i.e., may extend beyond a side of the first semiconductor chip 210 in a direction away therefrom.

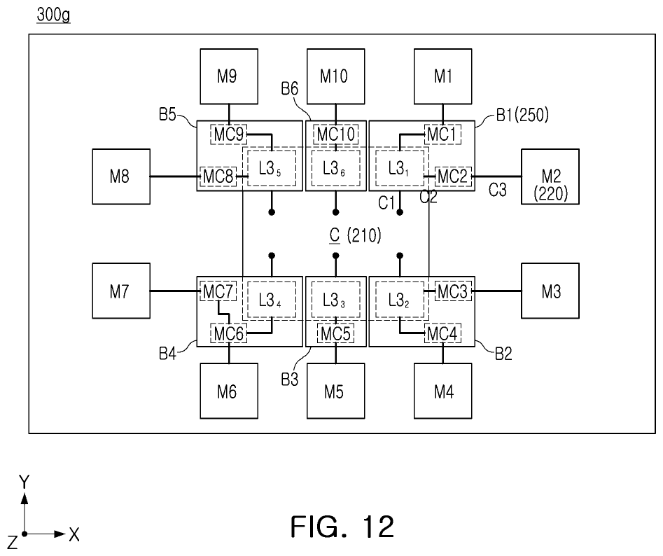

Referring to FIG. 12, in the semiconductor package 300g according to this embodiment, a first semiconductor chip 210 may be disposed in a central region of the semiconductor package 300g. The first semiconductor chip 210 may be disposed on the upper surface of the interposer 100, and second semiconductor chips 220 (M1 to M10) may be disposed on the upper surface of the interposer 100 and surround the first semiconductor chip 210. The number of the second semiconductor chips 220 (M1 to M10) can be variously set, and in FIG. 12, 10 second semiconductor chips 220 (M1 to M10) may surround the first semiconductor chip 210. Two of the second semiconductor chips 220 (M1 to M10) may be disposed on left and right sides thereof, and three second semiconductor chips 220 (M1 to M10) may be disposed thereabove and therebelow.

Therefore, unlike the semiconductor package 300f of FIG. 11, the semiconductor package 300g may further include a semiconductor chip M5 adjacent to a lower side of the first semiconductor chip 210 and a semiconductor chip M10 adjacent to an upper side of the first semiconductor chip 210. and the semiconductor package 300g may further include the bridge dies 250 (B3 and B6) corresponding thereto, and the semiconductor package 300g of FIG. 12 may include a total of six bridge dies 250 (B1 to B6).

In this case, each of first-type bridge dies 250 (B1, B2, B4, B5) may be connected to two of the second semiconductor chips 220 (M1 to M10) and each of second-type bridge dies 250 (B3, B6) may be connected to one of the second semiconductor chips (M5 and M10).

The first-type bridge die 250 (B1, B2, B4, B5) may occupy a greater area than the second-type bridge die 250 (B3, B6), and may include two memory controllers (M1, M2) therein, and the L3 cache memory can also have higher capacity. By disposing the second-type bridge dies 250 (B3 and B6) having a small area between the first-type bridge dies 250 (B1, B2, B4, B5), an additional bridge die may be attached according to the increasing number of the semiconductor chips 220, so that the bridge die 250 and the second semiconductor chip 220 may be selectively attached according to the required memory capacity without changing the design of the entire semiconductor package.

As described above, the bridge die 250 may be formed by forming some of the functional blocks of the first semiconductor chip 210 as a separate chip structure, and the bridge die 250 may include memory controllers MC and a cache memory L3.

Accordingly, the electrical signal from the first semiconductor chip 210 can be transmitted to the bridge die 250 through hybrid bonding C1. In the bridge die 250, the electrical signal may be transmitted to the second semiconductor chip 220 via an electrical connection including the connection between the second lower pad 253b and the vertical bump 240 and the pad connection C3 between the interconnection layer 172 of the interposer 100 and the second semiconductor chip 220. The electrical signal from the second semiconductor chip 220 can also be transmitted through the vertical bump 240 (C1), and the electrical signal from the second semiconductor chip 220 may be transmitted to the first semiconductor chip 210 through hybrid bonding C1. Accordingly, the cache memory L3 for storing data of the plurality of second semiconductor chips 220 may be shared in each bridge die 250, and even when six bridge dies 250 (B1 to B6) are disposed, a separate die may not be disposed in the central region of the first semiconductor chip 210, but may be disposed to be exposed externally.

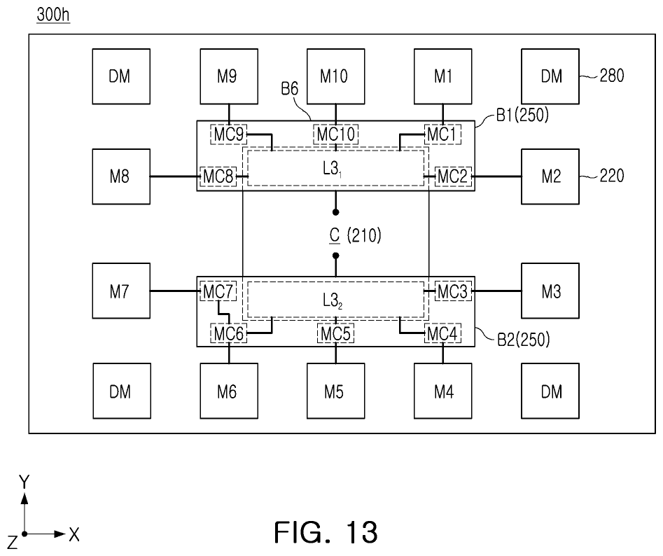

Referring to FIG. 13, in the semiconductor package 300h according to this embodiment, a first semiconductor chip 210 may be disposed in the central region on the upper surface of the interposer 100, and second semiconductor chips 220 (M1 to M10) may be disposed while surrounding the first semiconductor chip 210. The number of the second semiconductor chips 220 (M1 to M10) can be set in various manners, and in FIG. 8, 10 second semiconductor chips 220 (M1 to M10) may be centered on the first semiconductor chip 210, two second semiconductor chips 220 (M1 to M10) may be disposed on left and right sides thereof, and three second semiconductor chips 220 (M1 to M10) may be disposed thereabove and therebelow.

With respect to the semiconductor package 300f of FIG. 11, the semiconductor package 300h may further include one of the semiconductor chips (M5 and M10), one each thereabove and therebelow, and may include two bridge dies 250 (B1 and B2).

That is, the first bridge die 250 (B1) may be disposed thereabove, and may be connected through the vertical bump 240 and the interposer 100, to be connected to the five second semiconductor chips M1, M2, M8 to M10 above the central region of the first semiconductor chip 210.

The second bridge die 250 (B2) may be disposed therebelow, and may be connected through the vertical bump 240 and the interposer 100, to be connected to the five second semiconductor chips M3 to M7 below the central region of the first semiconductor chip 210.

The shape and configuration of the first and first bridge dies 250 (B1 and B2) may be the same, and a separate die may not be disposed in the central region of the first semiconductor chip 210 but may be disposed to be exposed externally. The first and first bridge dies 250 (B1 and B2) may include memory controllers (MC1 to MC10) connected to each memory, and may be connected to share the L3 cache memory (L3₁ and L3₂).

In this case, when 10 second semiconductor chips (M1 to M10) are disposed, there is a separation space between the second semiconductor chips (M1 to M10), specifically, a region without the second semiconductor chips (M1 to M10) in each corner region of semiconductor package 200h, and a dummy chip DM 280 may be further included to prevent the corner region from collapsing.

In FIG. 13, when a plurality of second semiconductor chips (M1 to M10) are disposed in the semiconductor package 300h, in order to prevent collapse in a spaced region in which the second semiconductor chips M1 to M10 are not disposed, a three-dimensional structure with density, similar to that of the second semiconductor chips (M1 to M10) may be disposed to prevent substrate warpage. The dummy chip DM 280 may include a material with similar thermal conductivity and density to that of the second semiconductor chips (M1 to M10), and may include a material such as bulk silicon, or the like, to expand the heat dissipation function.

As set forth above, according to the above-described embodiments, by forming some functional blocks of a logic chip into individual chips and attaching the same as a bridge die (e.g., semiconductor bridge) onto the logic chip, an area of the logic chip may be reduced on the package.

In particular, a size of a cache memory may be further expanded by separating a memory controller directly connected to the plurality of memory chips and the cache memory occupying a large area with the memory controller, into a separate bridge die and vertically disposing the same.

In particular, by implementing various numbers of bridge dies disposed above the logic chip, it is possible to implement bridge dies with the optimal number and optimal shape according to the number of memory chips.

The various and advantageous advantages and effects of the present inventive concept are not limited to the above description, and may be more easily understood in the course of describing the specific embodiments of the present inventive concept. While example embodiments have been shown and described above, it will be apparent to those skilled in the art that modifications and variations could be made without departing from the scope of the present inventive concept, as defined by the appended claims.

While example embodiments have been shown and described above, it will be apparent to those skilled in the art that modifications and variations could be made without departing from the scope of the present inventive concept as defined by the appended claims.

What is claimed is:

1. A semiconductor package comprising:
a first semiconductor chip including a semiconductor substrate and a plurality of upper bonding pads disposed on an upper surface of the semiconductor substrate; and
a bridge die disposed on the first semiconductor chip, and including a bridge substrate and a plurality of first lower pads,
wherein the bridge substrate includes a first bridge portion and a second bridge portion,
wherein the plurality of first lower pads are disposed on a first lower surface of the first bridge portion of the bridge substrate and contact the plurality of upper bonding pads of the first semiconductor chip, respectively,
wherein, when viewed in a plan view, the first bridge portion overlaps an edge portion of the first semiconductor chip and the second bridge portion extends beyond a side of the first semiconductor chip in a direction away from the edge portion of the first semiconductor chip, and
wherein the bridge die and the first semiconductor chip are different types of semiconductor devices.

2. The semiconductor package of claim 1,
wherein the bridge die further includes a plurality of second lower pads,
wherein the plurality of second lower pads are coplanar with the plurality of first lower pads,
wherein the plurality of second lower pads are disposed on a second lower surface of the second bridge portion of the bridge substrate, and
wherein the first lower surface of the first bridge portion and the second lower surface of the second bridge portion are included in a lower surface of the bridge substrate.

3. The semiconductor package of claim 2,
wherein the bridge die further comprises a lower insulating layer disposed below the bridge substrate and exposing each of the plurality of first lower pads,
wherein the first semiconductor chip further comprises an upper insulating layer disposed on the upper surface of the semiconductor substrate and exposing each of the plurality of upper bonding pads, and
wherein the lower insulating layer and the upper insulating layer contact each other, and each of the plurality of first lower pads and a corresponding one of the plurality of upper bonding pads contact each other to form hybrid bonding.

4. The semiconductor package of claim 2,
wherein each of the plurality of first lower pads has a first width,
wherein each of the plurality of second lower pads has a second width, and
wherein the second width is greater than the first width.

5. The semiconductor package of claim 2,
wherein the semiconductor package further comprises:
a redistribution structure disposed below the first semiconductor chip, and including an insulating layer and an interconnection layer disposed within the insulating layer,
wherein the redistribution structure further includes a plurality of first upper contact pads disposed on an upper surface of the insulating layer and connected to a plurality of lower bonding pads of the first semiconductor chip, respectively.

6. The semiconductor package of claim 5,
wherein the redistribution structure further includes a plurality of second upper contact pads on the upper surface of the insulating layer,
wherein the semiconductor package further comprises a plurality of vertical conductive structures connecting the plurality of second lower pads of the bridge die and the plurality of second upper contact pads of the redistribution structure with each other, respectively, and
wherein, when viewed in a plan view, the plurality of vertical conductive structures are disposed outside of the first semiconductor chip.

7. The semiconductor package of claim 6,
wherein each of the plurality of vertical conductive structures has a width in a range of 150 μm to 250 μm.

8. The semiconductor package of claim 7,
wherein the plurality of vertical conductive structures are spaced apart from each other at a separation distance in a range of 200 μm to 300 μm.

9. The semiconductor package of claim 1,
wherein the first semiconductor chip further comprises a plurality of first through-electrodes connected to the plurality of upper bonding pads, and penetrating the semiconductor substrate.

10. The semiconductor package of claim 9,
wherein the bridge die further comprises a plurality of second through-electrodes connected to the plurality of first lower pads of the bridge die, and penetrating the bridge substrate.

11. The semiconductor package of claim 1,
wherein the first semiconductor chip is a processor, and
wherein the bridge die includes a cache memory of the processor.

12. A semiconductor package comprising:
a redistribution structure including an insulating layer and an interconnection layer disposed within the insulating layer, and including a plurality of first upper contact pads and a plurality of second upper contact pads disposed on an upper surface of the insulating layer;
a first semiconductor chip disposed on the redistribution structure and having a semiconductor substrate and a plurality of upper bonding pads disposed on an upper surface of the semiconductor substrate;
at least one second semiconductor chip disposed around the first semiconductor chip on the redistribution structure;
a bridge die disposed on the first semiconductor chip, and including a bridge substrate and a plurality of first lower pads and a plurality of second lower pads disposed on a lower surface of the bridge substrate,
wherein the bridge substrate includes a first bridge portion and a second bridge portion,
wherein the plurality of first lower pads are disposed on a first lower surface of the first bridge portion of the bridge substrate and contact the plurality of upper bonding pads, respectively,
wherein the plurality of second lower pads are disposed on a second lower surface of the second bridge portion of the bridge substrate,
wherein the first lower surface of the first bridge portion and the second lower surface of the second bridge portion is included in the lower surface of the bridge substrate, and
wherein, when viewed in a plan view, the first bridge portion overlaps an edge portion of the first semiconductor chip and the second bridge portion extends beyond a side of the first semiconductor chip in a direction away from the edge portion of the first semiconductor chip; and
a plurality of vertical conductive structures connecting the plurality of second lower pads of the bridge die to the plurality of second upper contact pads of the redistribution structure, respectively.

13. The semiconductor package of claim 12,
wherein the plurality of first upper contact pads are disposed below the first semiconductor chip and the at least one second semiconductor chip.

14. The semiconductor package of claim 13,
wherein the plurality of the vertical conductive structures comprise a plurality of bumps vertically connecting the plurality of second upper contact pads of the redistribution structure and the plurality of second lower pads of the bridge die.

15. The semiconductor package of claim 12,
wherein the second bridge portion of the bridge die extends into a separation space between the first semiconductor chip and the at least one second semiconductor chip.

16. The semiconductor package of claim 12,
wherein at least second semiconductor chip is electrically connected to the plurality of vertical conductive structures through the interconnection layer of the redistribution structure.

17. The semiconductor package of claim 12,
wherein the bridge die is repeatedly positioned on an upper surface of the first semiconductor chip to form a plurality of bridge dies,
wherein the plurality of bridge dies overlap an edge portion of the first semiconductor chip and, when viewed in a plan view, defines a central region of the first semiconductor chip, and
wherein the plurality of bridge dies are symmetrically arranged relative to the central region.

18. The semiconductor package of claim 12,
wherein, when viewed in a plan view, the bridge die further overlaps a central region of the first semiconductor chip,
wherein the bridge die comprises a heat dissipation portion above the central region of the first semiconductor chip, and
wherein an area of the bridge die is greater than an area of the first semiconductor chip.

19. The semiconductor package of claim 12,
wherein the first semiconductor chip is a processor,
wherein the at least one second semiconductor chip is a memory structure including a plurality of memory chips stacked on each other, and
wherein the bridge die comprises a cache memory of the first semiconductor chip and a memory controller controlling the memory structure.

20. A semiconductor package comprising:
a redistribution structure;
a first semiconductor chip disposed on the redistribution structure;
a plurality of second semiconductor chip disposed around the first semiconductor chip on the redistribution structure;
a first-type bridge die partially overlapping the first semiconductor chip;
a second-type bridge die partially overlapping the first semiconductor chip,
wherein an area of the first-type bridge die is greater than an area of the second-type bridge die; and
a plurality vertical conductive structures connecting each of the first-type bridge die and the second-type bridge to the redistribution structure,
wherein the first-type bridge die is electrically connected to M semiconductor chips among the plurality of second semiconductor chips,
wherein the second-type bridge die is electrically connected to N semiconductor chips among the plurality of second semiconductor chips,
wherein the first-type bridge die includes M memory controllers and a first cache memory,
wherein the second-type bridge die includes N memory controllers and a second cache memory,
wherein M is an integer equal to or greater than 2, N is an integer equal to or greater than 1, and M is greater than N, and
wherein a memory capacity of the first cache memory is greater than a memory capacity of the second cache memory.
